(19) United States
(12) Patent Application Publication
(10) Pub. No.: US 2008/0156255 A1
(43) Pub. Date: Jul. 3, 2008

(54) Apparatus And Process For Crystal Growth

(76) Inventors: Arnab Basu, Durham (GB); Max Robinson, Durham (GB); Ben Cantwell, County Durham (GB); Andy Brinkman, Durham (GB)

Correspondence Address: POPOVICH, WILES & O'CONNELL, PA;650 THIRD AVENUE SOUTH, SUITE 600, MINNEAPOLIS, MN, 55402, US

(21) Appl. No.: 11/816,807

(22) PCT Filed: Feb. 2, 2006
(86) PCT No.: PCT/GB2006/000354

§ 371 Date: Feb. 1, 2008

(30) Foreign Application Priority Data
Feb. 22, 2005 (GB) 0503634.8

(51) Int. Cl. C30B 31/00; C30B 35/00; C30B 23/00

(52) U.S. Cl. 117/2; 117/200; 117/201; 117/84

(57) ABSTRACT

The present invention relates to an apparatus for vapour phase crystal growth to produce multiple single crystals in one growth cycle comprising one central source chamber, a plurality of growth chambers, a plurality of passage means adapted for transport of vapour from the source chamber to the growth chambers, wherein the source chamber is thermally decoupled from the growth chambers.

### TECHNICAL FIELD

The present invention relates to an improved apparatus and process for vapour phase crystal growth, and crystals obtained with the apparatus or process.

### BACKGROUND OF THE INVENTION

In designing an effective vapour growth system which has the potential for commercial development and the production of large, highly qualified single crystals of semiconducting materials with for example cadmium telluride (CdTe), there are three major concerns including the achievement of an adequate growth rate, the need to achieve high quality single crystal over a 50 mm and larger diameter boule; and the requirement for a user friendly, robust, manufacturable but flexible design.

Until fairly recently conventional vapour transport has involved the use of a simple linear system with a source and sink of single crystals of II-VI compounds, such as CdS, ZnSe, which sublime easily from the solid phase. These together with a seed crystal are located in a sealed quartz ampoule in a tubular furnace in an arrangement for example as described in W. W. Piper and S. J. Polich, J. Appl. Phys. 32 (1961) 1278. The source and sink are at different temperatures and therefore have different equilibrium vapour pressures. This vapour pressure difference provides the driving force for growth.

This approach results in certain fundamental problem for growth of crystals such as CdTe:

The equilibrium vapour composition of CdTe is non-stoichiometric except at one temperature, the congruent evaporation temperature which is described in more detail in D. de Nobel Philips Res. Repts. 14 (1959) 361. Due to the law of mass action:

[Cd][Te₂]^{1/2}=K(T)

where [Cd] and [Te₂] are the concentrations of cadmium and tellurium vapour respectively and K is a constant depending on temperature, T. N. Yellin and S. Szapiro, J. Crystal Growth 69 (1984) 555 have reported that minute deviations from stoichiometry in the bulk source material result in large variations in the composition of the vapour making the transport and hence growth highly non-reproducible. Furthermore, this effect gives rise to non-stoichiometry in the growing crystal which has a detrimental effect on its useful properties.

Attempting to overcome these problems with the use of high source/sink temperatures is very difficult and does not lead to a significant improvement in growth rate.

Alternatively, control of the axial temperature gradient is also difficult in simple closed tubular systems and it is difficult to thermally isolate source and sink regions as radiation is an important thermal flux. Furthermore, exact determination of the parameters controlling growth (i.e. surface temperatures of source and seed, vapour pressures) is difficult.

This approach may be improved by the use of a reservoir containing one of the constituent elements to control the partial pressures according to the above equation. A limitation with this approach in a typical growth system is that the exact conditions of temperature and partial pressure are not determined directly and so the optimum reservoir temperature may be uncertain requiring analysis of grown crystals. This problem is compounded, in a system without in-situ monitoring, by any change in conditions during a growth run and run to run variations.

Another major advance in overcoming the limitations of this technology was proposed by the NASA/University of Alabama group of Rosenberger, Banish and Duval (RBD) in F. Rosenberger, M. Banish and W. M. W. Duval, NASA Technical Memorandum 103786. Their design was a tubular system with a flow restrictor between the source and the seed. A small proportion of the source material and in particular any excess material was removed preferentially through continuously pumped effusion holes, thus maintaining a near stoichiometry of the vapour phase. The first flow restrictor acted to make the mass transport rate relatively insensitive to the temperatures of the source and sink and their difference. If not restricted in this way, in a system operating under near stoichiometric conditions, appropriate transport rates would require the temperature difference between source and sink to be controlled to within a small fraction of a degree which is difficult especially if the temperatures of the source and growing surfaces cannot be measured directly. This system does, however, suffer from some significant limitations including thermal coupling along the axis of the furnace prevented the desired axial temperature profile from being obtained, direct determination of the surface temperatures of source and seed was not possible, and indirect determination uncertain due to the complexity of the radiation field, the partial pressures of source species over the source and the seed were not directly measurable and uncertainties in the flow modelling of the system and its restrictions made indirect determination uncertain and the quartz ware was complex, not easy to use and vulnerable in application.

U.S. Pat. No. 5,365,876 discloses an optically transparent furnace and detector apparatus. The crystal grows by transport of vapour along a temperature gradient in an evacuated ampoule. The temperature gradient between the surface of the crystal and the source material determines the growth rate of the crystal. DE4310744 discloses an apparatus and method for bulk vapour crystal growth which comprises a passage for transport of vapour connecting a source and growth chamber. The passage for transport vapour is in a straight line direction along the length between source and growth chamber. Thus, the source and growth chambers are not thermally separated/decoupled and the production of multiple crystals in one growth cycle is not possible in either U.S. Pat. No. 5,365,876 or DE4310744.

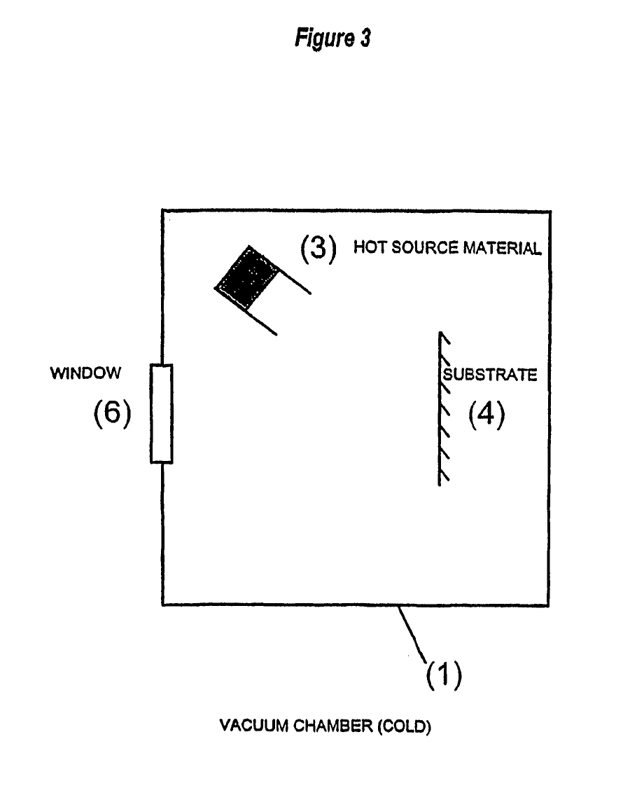

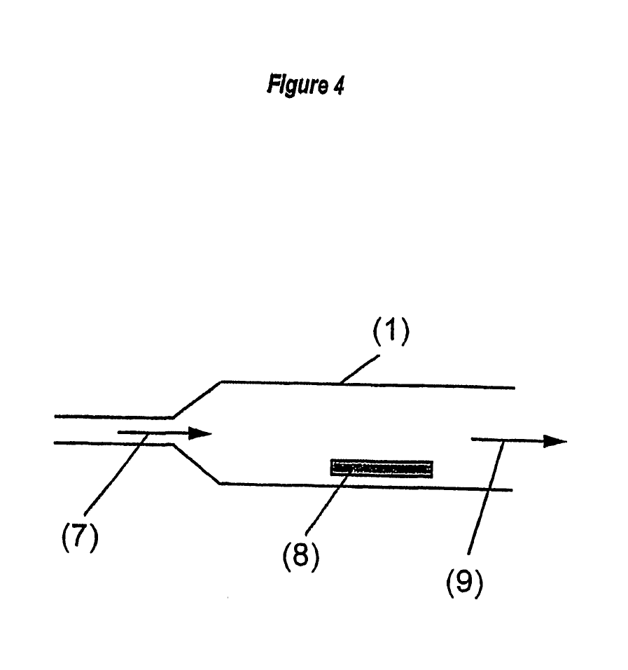

In-situ optical monitoring is known and routinely employed in other methods such as low temperature thin film growth, where the ‘efficiency’ of the process is not very important. Examples of this are Molecular Beam Epitaxy (MBE) (see FIG. 3) and Metal-Organic Vapour Phase Epitaxy (MOVPE) (see FIG. 4) however these techniques are not suitable for ‘bulk’ crystal growth which requires enclosed transport passages for efficient source utilisation and also requires heating of the quartz passages to allow optical access while preventing condensation prior to the growth region.

EP 1,019,568 B1 discloses an apparatus and method for bulk vapour crystal growth which comprises a passage for transport of vapour connecting a source and growth chamber where the passage deviates by an angle of at least 5° along the length of the passage between source and growth chambers. An apparatus comprising a plurality of source zones and a single growth chamber is also contemplated. This vapour growth system allows the production of large, high quality single crystals of semi-conducting materials with effective temperature and stoichiometry control. EP 1 019 568 B1 also discloses an apparatus and method for vapour phase crystal growth which enables in-situ monitoring in non-intrusive manner and moreover allows for substantial thermal isolation of source and sink regions by thermally separating the source material chamber from the seed crystal chamber.

The production costs of the known techniques are high. Thus, there remains the need for an apparatus for the large scale production of multiple crystals. Furthermore, there also remains the need for the production of multiple crystals with differing properties and sizes.

The present invention addresses these problems by proposing a means of producing multiple single crystals during one growth cycle. This will allow higher yields of the crystals compared with conventional techniques and result in lower production costs. It also enables the simultaneous production of crystals having different diameters and even different electrical properties.

### SUMMARY OF THE INVENTION

According to one aspect of the invention, there is provided an apparatus for bulk vapour phase crystal growth comprising:
at least one central source chamber;
a plurality of growth chambers;
a plurality of passage means adapted for transport of vapour from the source chamber to the growth chambers wherein the at least one source chamber is thermally decoupled from the growth chambers.

Preferably, the apparatus comprises at least one central source chamber surrounded by a number of satellite growth tubes each containing a seed crystal. All the tubes are thermally decoupled from each other. The vapour from the source material is drawn into each growth tube using a pumping mechanism. By employing this technique a number of crystals can all be grown at the same time. Each individual growth chamber can be independently controlled in terms of temperature and vapour flow rate.

It will be understood that the terms “sink” zone or region and “growth chamber” when used in this specification are interchangeable.

There are several advantages associated with an apparatus comprising a plurality of growth chambers including

(i) different diameters of material can be produced depending on the customer requirement;
(ii) different compositions can be produced (e.g. varying the Zn % in CZT, 4% Zn suitable for substrate market, 10% Zn suitable for detector applications);
(iii) dopants can be introduced wherein the doping levels can be varied, enabling simultaneous production of material with different electrical resistivity.

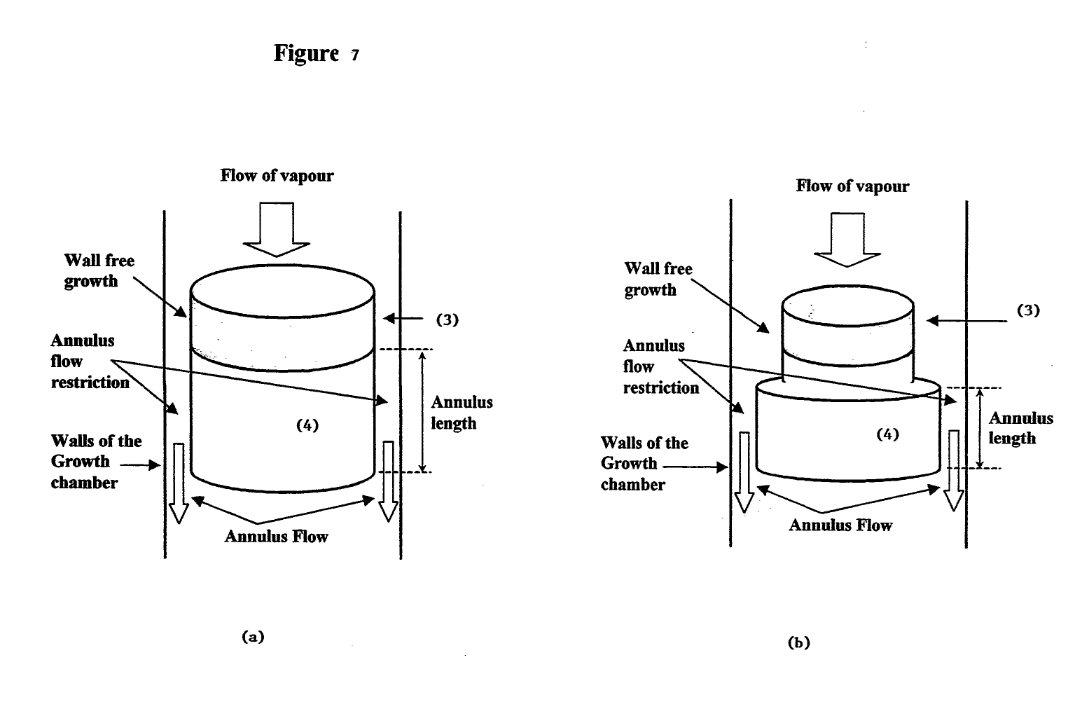

A further aspect of this invention is that in addition to the number of crystals being grown at the same time, the crystals may have varying diameter. This is effected by changing the shape of the pedestal which the seed crystal is mounted upon. The pedestal provides an annulus flow restriction (FIG. 7(b)). Annulus flow restriction is achieved by a combination of the annulus gap i.e. the distance between the pedestal and side wall of the growth chamber and length of the pedestal. By modifying the shape of the pedestal, the size of the crystal to be grown and the flow restrictor function can be decoupled/separated. Furthermore, the annulus gap allows the removal of impurities and excess vapours, thereby allowing the production of purer crystals.

Furthermore, it is possible to add dopant impurities at different levels into each individual growth chamber. These dopant impurities have the effect of changing the important electrical properties of the crystal, such as resistivity, carrier mobility and carrier lifetime. Due to flow restriction and the positive pumping within the system there is no significant cross contamination between the dopant levels of each individual crystal.

Theoretical calculations have shown that the maximum resistivity that can be obtained after chemical and physical purification of CdTe is about 10⁸ ohm cm¹. However in practice the resistivity of CdTe produced by all methods lies in between 10⁴ to 10⁶ ohm cm. However, the electrical resistivity of CdTe needs to be in excess of 10⁸ ohm cm for it to be used as a radiation detector. Therefore, it is preferable to dope CdTe with elements such as chlorine to make it suitable for application as detectors. Suitable dopants according to the invention include chlorine, indium, copper, zinc.

Chlorine can be added by subliming CdCl or a solid solution of CdTe and CdCl from the source chamber. The vapour can be transported through a multilayered quartz crossmember through a flow restrictor which allows transport only to specific growth chambers. This restricts cross contamination and allows growth of crystals with and without doping. Depending on the design of the crossmember the dopant vapour can be transported to one or all the growth chambers and the flow rate to each of the growth chambers can be altered by changing the size of the flow restrictors to the individual growth chambers.

Thus, the present invention enables the growth of a number of individual crystals during the same growth cycle. Preferably, the present invention enables the simultaneous growth of at least two crystals of different properties. For example, crystals of different diameter can be grown at the same time. Furthermore, if desired, crystals of distinctly different electrical properties can also be grown at the same time.

Means for independent temperature control enable the establishment of a temperature differential to enable solid-vapour-solid phase transition in the respective source, transport and growth chambers/growth chambers. Temperature control may therefore be selected according to the phase transitions for any given crystal which it is desired to grow, for example in the range from −150° to +2000° C., employing in each case a greater source than sink/growth chamber temperature with use of appropriate cooling and/or heating control.

Preferably, means for in-situ monitoring of crystal growth are present, which comprise means for providing visual and/or radiation access to the growth zone but located remote therefrom. More preferably means for direct monitoring of crystal growth comprise at least one passage for monitoring communication between the remote visual/radiation access means and the growth chamber, wherein the at least one passage for monitoring communication and the at least one passage for transport of vapour associated with any given growth chamber are coincident for at least that portion of their length proximal to the zink zone.

It is a particular advantage of the invention that the apparatus as hereinbefore defined may be operated with use of conventional or modified visual/radiation monitoring means, located external to the passages as hereinbefore defined, by means of the visual/radiation access means, for example x-ray and the like may be employed to monitor crystal growth. Moreover, the apparatus of the invention may be employed in any bulk vapour transport technique with associated advantages in crystal quality, thereby overcoming disruption of growth conditions which are inherent with known in-situ monitoring means proximal to the growth chamber.

Reference herein to locations remote from the at least one growth chamber is to locations at which the presence of access means as hereinbefore defined introducing temperature variation or gradient in the vapour transport passage would substantially not disrupt the conditions of temperature required for uniform growth, having regard to conditions of temperature created by means of temperature controlling means for the at least one growth chamber. In contrast reference herein to locations proximal to the at least one growth chamber are to locations which would be subject to substantial disruption of conditions of temperature under these circumstances.

In a further aspect, the present invention provides an apparatus as hereinbefore defined wherein at least one of the passage for visual/radial communication and the passage for vapour transport associated with any given growth chamber deviates by an angle of at least 5°-270°, more preferably 30°-180°, most preferably 45°-110°, for example 60°-95°.

Accordingly the passage for vapour transport may deviate by an angle as hereinbefore defined whereby means for visual/radiation access may be located in the wall of the passage for vapour transport in direct line communication with the growth chamber. For example means for visual/radiation access may comprise a visual/radiation-transparent port sealed into an optionally continuous with the wall of the transport passage, located opposing to the sink surface.

Alternatively the configuration of respective passage for visual/radiation access and for visual/radiation access and vapour transport as hereinbefore defined may be reversed, whereby the passage for visual/radiation monitoring may deviate by an angle as hereinbefore defined from a direct line communication of source and growth chamber. In this case means for visual/radiation monitoring at its point of deviation, whereby virtual or reflected direct line access is provided with the growth chamber. For example a reflective or transmissive means such as mirrored or prism quartz may be provided in association with the visual/radiation monitoring passage at its point of deviation.

Preferably, the apparatus as hereinbefore defined comprises at least one passage for transport as hereinbefore defined, which deviates by an angle of at least 5° as hereinbefore defined along the length thereof between source and growth chambers. More preferably the passage deviates by at least 5° at two points along the length thereof whereby both zones are adapted to comprise source and sink material free from constraints of gravity, i.e. which are substantially provided on suitable support means and with the passage means extending substantially upwardly therefrom, thereby providing for optimal transport with minimum disruption of the growth process.

It is a further advantage of the apparatus of the present invention that both objects of accurate temperature control of source and growth chambers and non-intrusive monitoring of at least the growth chambers can be achieved in mutually beneficial manner, whereby positioning of monitoring access means between dedicated temperature control means prevents disruption proximal to either zone.

It is a further advantage of the invention that the apparatus is ideally suited to inclusion of a flow restrictor, for example as proposed by NASA/University of Alabama RBD group above, located remote from both zones, for example upstream of sink monitoring means, for the purpose of vapour pressure control. Preferably in-situ means for monitoring vapour pressure is provided associated with a flow restrictor, in the form of known vapour pressure monitoring apparatus, for example as described in J. Carles, J. T. Mullins and A. W. Brinkman, J. Crystal Growth, 174 (1997) 740, the contents of which are incorporated herein by reference.

Flow restrictions may be selected from any know restrictions and preferably comprises a capillary, porous sintered disc or the like.

The apparatus of the invention is suitably constructed of any material which is adapted for use at the temperatures envisaged for crystal growth, for example is constructed of low, ambient and high temperature resistant materials. Suitable materials are know in the art and preference is given to metal oxides, and in particular quartz, refractory oxides and graphite having the required mechanical strength and integrity, for example being reinforced with a suitable material providing mechanical strength and integrity These materials are also preferred for reason of their high purity with low risk of contamination of crystal. Preferably, the apparatus comprises a sealed or sealable structure or envelope including zones and passages as hereinbefore defined. The apparatus is suitably operated at reduced pressure and is encased in a vacuum jacket or the like.

The apparatus of the invention may be used for any bulk vapour transport techniques as hereinbefore defined. It is a particular advantage that the apparatus is adapted for growth of crystals from elemental, polycrystalline binary, ternary or other multinary compounds. It is a further advantage that the apparatus of the invention is suited for use with growth from elemental, binary, ternary of other multinary compounds requiring stoichiometry control to compensate for a degree of non-stoichiometry in vapour composition of the desired crystal. The source and growth chambers are adapted to comprise source material and seed crystal as known in the art, for example in the form of one or more reservoirs of source material comprise material in solid phase supported on a glass or other suitable surface or pedestal adapted to the processing conditions to be employed, allowing convenient and efficient vaporisation wherein vapour is transported through a path, which may deviate by an angle of at least 5° along the length thereof between source and sink crystals, thereby thermally isolating the source and growth regions.

Preferably means for monitoring radiation and transport for any given sink or seed is by coincident monitoring and transport path for at least the portion of the respective paths proximal to the sink or seed, as hereinbefore defined.

Preferably the process is operated at reduced ambient or elevated temperature as hereinbefore defined. The process is moreover operated at reduced pressure, for example in the range from 10 bar, preferably 10⁻⁹ mbar to 10² mbar up to 1 bar. The process may be started up by known means to establish a sufficient vapour pressure above source material to initiate growth.

In a further aspect of the invention there is therefore provided a method for starting up the process as hereinbefore defined in a manner to establish a sufficient vapour pressure above the source material to initiate transport.

In a further aspect of the invention there is therefore provided a method for starting up the process as hereinbefore defined in a manner to establish transport control and temperature to control in the growth chamber for controlled growth at the sink or seed.

The method for starting up is suitably operated with temperature and transport rate ramping profiles. It is a particular advantage that independent temperature control means provided with the apparatus of the invention enables temperature ramping specific to growth at the sink or seed, which may also be at a temperature lower than that at the source. It is thought that this gives rise to excellent crystal quality and may even prevent an amount of precipitation or eliminate precipitation entirely.

The process is suitably operated with means for in-situ monitoring as hereinbefore defined according to known techniques. Preferably, temperature is monitored by known means at the surface of the sink, and optionally of the source, in a manner to enable adjustment as required for optimum temperature control and stoichiometry. Likewise vapour pressure is suitably monitored between zones, for example at the location of a flow restrictor and may be adapted or adjusted as required for optimum growth.

Preferably, the process of the invention as hereinbefore defined additionally comprises direct reading of process variables, comparison with optimum values of process variables for a desired crystal growth, for example, with use of a process model, and on line optimisations thereof.

The apparatus and process of the invention as hereinbefore described are adapted for growth of any crystal employing bulk vapour transport techniques.

In a further aspect of the invention, there is provided a crystal grown with the apparatus or process of the invention. The invention is suited for growth of crystals comprising any compounds which are capable of being sublimed, having a significant vapour pressure below their melting point. Preferably crystals are selected from compounds of groups IIA, IIB, III, V, I and VII of Group IV, more preferably of groups II and V or Group IV of the Periodic Table of the Elements, for example selected from Be, Mg, Zn, Cd, Hg, S, Se, Te and I or from Si and C. Particularly useful crystals grown with the apparatus and process of the invention include cadmium telluride.

In a further aspect of the invention, there is provided the use of known monitoring equipment to monitor crystal growth with the apparatus and process of the invention.

In a still further aspect of the invention, there is provided the use of the apparatus or process of the invention for any vapour transport technique for growing semiconductor, optoelectronic and optical crystals. These crystals may be used in applications such as radiation detection, substrates for functional thick and thin films, optical elements and targets for sputtering, e beam evaporation and other techniques.

The invention is now illustrated in non-limiting manner with reference to the following figures wherein:

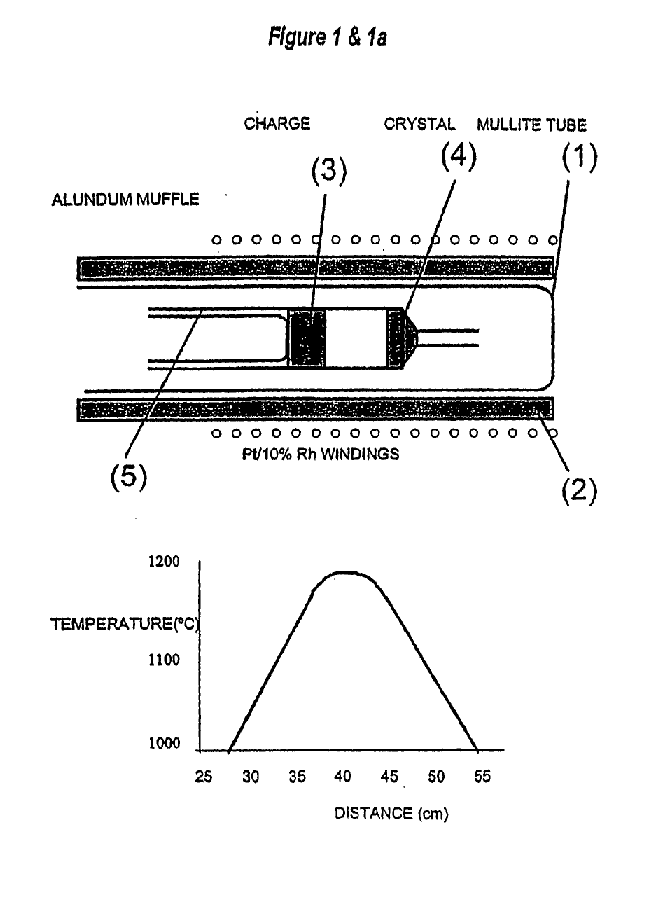

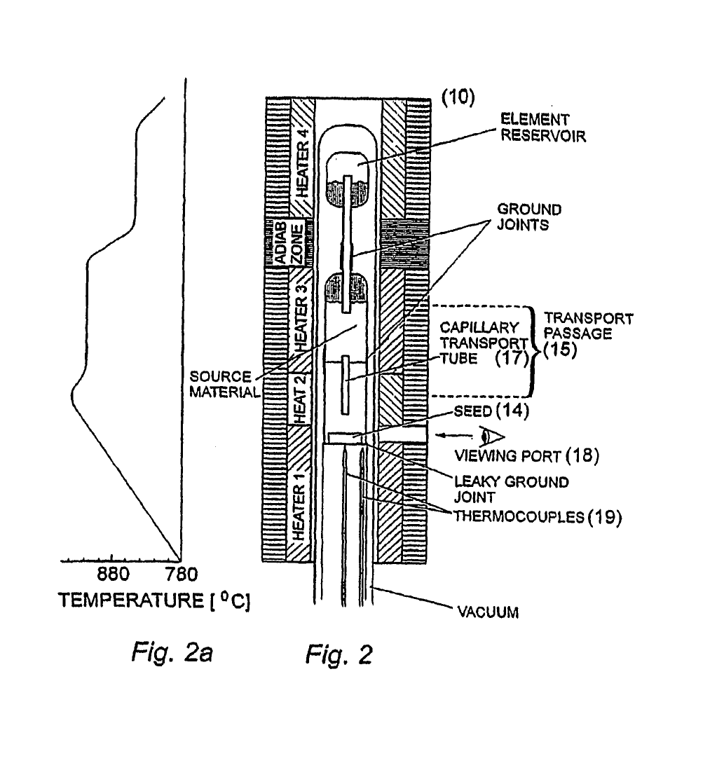

FIG. 1 and FIG. 2 are illustrative of prior art bulk vapour phase crystal growth apparatus;

FIG. 3 and FIG. 4 are illustrative of prior art MBE and MOVPE apparatus;

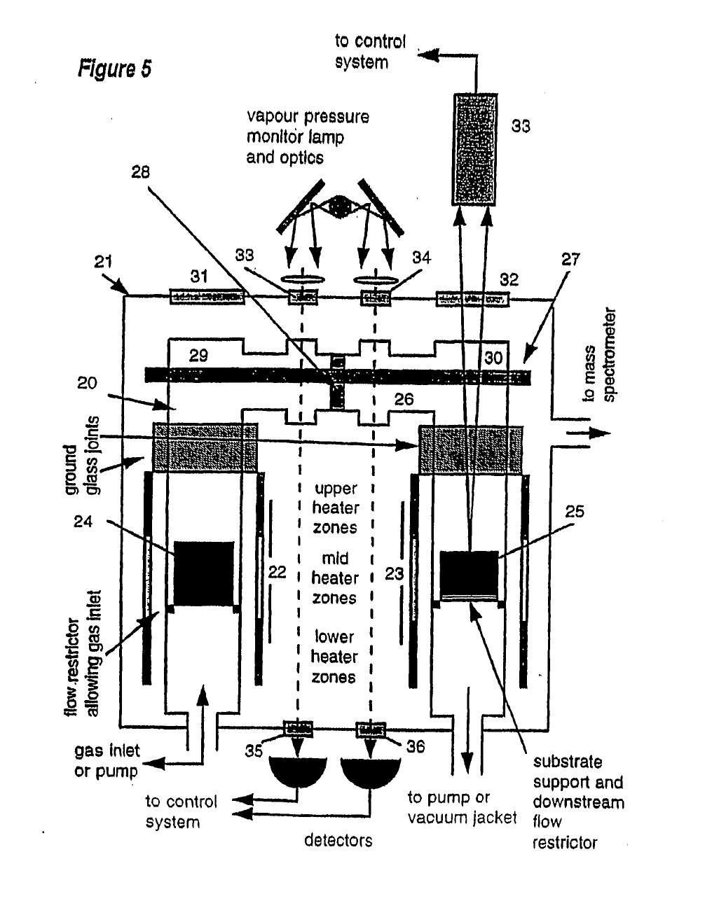

FIG. 5 is illustrative of the apparatus of EP 1 019 568; and

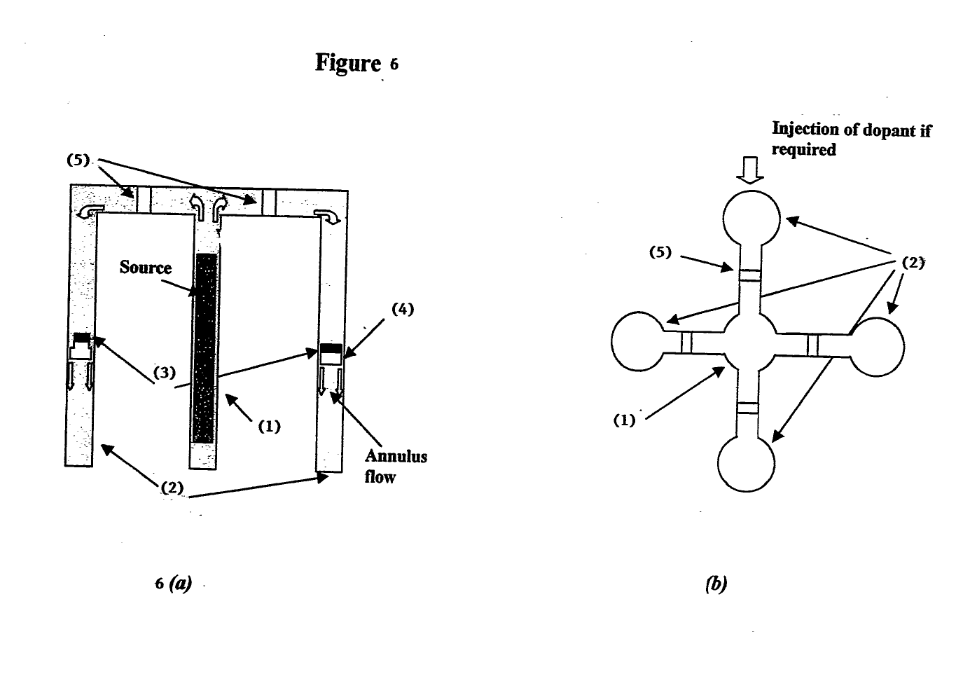

FIGS. 6 and 7 are diagrammatic schemes of apparatus according to the present invention.

FIG. 1 shows a simple linear system for vapour crystal growth comprising a sealed quartz ampoule (1) in a tubular furnace (2) have a source (3) and sink (4) for growth of cadmium sulphide, comprised in a growing crucible (5). The source and sink (3 and 4) are not thermally isolated. Moreover, there is no means for in situ monitoring of temperature or vapour pressure.

In FIG. 2 is illustrated vapour phase crystal growth apparatus comprising a tubular system with a flow restrictor as designed by RB group University of Alabama. The apparatus comprises a pressure vessel (10, independent heaters (11-13) for respective sink, transport passage and source zones (14-16) having a capillary transport tube (17) as flow restrictor therebetween. A viewing port (18) located adjacent to the growth chamber (14) provides optical access to the growing crystal in the growth chamber (14). In the temperature profile shown in FIG. 2a it is clear that relatively stable temperatures are achieved in each zone as a result of the thermal isolation, however a slight irregularity is apparent at the level of viewing port (18) adjacent to the growth chambers, which results from a break in the cladding in order to provide the viewing access adjacent the crystal. The temperature profile shows a staged variation reaching a maximum flow restrictor (17) with graduated temperature decrease across the growth chamber (14).

In FIG. 3 is shown a prior art MBE apparatus as hereinbefore described comprising vacuum chamber (1) having a temperature controlled source (3) and a temperature controlled sink (4). In situ monitoring means are provided (6) located opposite to the sink (4). Efficient source utilisation is not a concern in the process, and much of the source material sticks to the cold vacuum chamber wall.

In FIG. 4 is shown a prior art MOVPE apparatus comprising a quartz envelope (1) having at one end an inlet for a metal organic source in carrier gas (7) and comprising a heated substrate (8) on to which the metal organics pyrolyse. Exhaust gases exit via outlet (9). Optical access via the quartz envelope (1) allows for in situ monitoring of the growing crystal and vapour phase conditions. However, this technique is not suitable for the growth of “bulk” crystals as the growth rates are limited and the requisite precursor metal organics are extremely expensive, especially as is in general the case, much is lost to the exhaust.

FIG. 5 shows the apparatus of EP 1 019 568 in a preferred embodiment adapted for elevated temperature bulk vapour phase crystal growth. The apparatus comprises an evacuated U-tube in the form of a quartz envelope (20) encased in a vacuum jacket (21). Two separate three zone vertical tubular furnaces are provided (22 and 23) for the source zone (24) and the growth chamber (25) respectively.

The source and growth chambers are connected by passage means (26) for vapour transport comprising an optically heated horizontal cross member (27). Flow restrictor (28) is provided in passage (26). The passage for vapour transport comprises two separate points of deviation in each case at an angle of 90° providing respective junctions between diverging passages for in situ monitoring and vapour transport from source zones (29), and to growth chamber (30). Access means are provided (31 and 32) comprising windows allowing other optical access to source and sink respectively. In the apparatus as shown in situ means for monitoring of temperature of the surface of growing crystal in the growth chamber (25) are provided in the form of a pyrometer or other optical diagnostic apparatus (33) located external to the vacuum jacket and in optical communication with the surface of the growing crystal. The diagnostic apparatus is in communication with a suitable control system to vary the growth chamber temperature. The apparatus comprises additionally means for in situ monitoring of vapour pressure by further access ports (33 to 36) in the region of the flow restrictor (28), through which vapour pressure monitoring lamps and optics may be directed from a position external to the vacuum jacket with detectors located as shown at a location (35 and 36) diametrically opposed with respect to the passage for vapour transport (26). These are suitably linked to a control system providing for process control.

FIG. 6(a) shows a side view of the apparatus of the present invention. FIG. 6(b) shows a plan view of this apparatus. These figures show a central source chamber (1) surrounded by a number of satellite growth tubes (2) each containing a seed crystal (3) supported on a seed pedestal (4). It will be appreciated that more than one central source chamber may be provided, connected to some or all of the satellite growth tubes. All the tubes are thermally decoupled from each other by means of a capillary flow restrictor (5). The vapour from the source material is drawn into each growth tube using a pumping mechanism as shown by the arrows in FIG. 6(a). By employing this technique a number of crystals can all be grown at the same time. Each individual growth chamber can be independently controlled in terms of temperature and vapour flow rate, thereby allowing the production of multiple crystals which may be of different diameter, as expanded below. The flow rate is controlled by a combination of the capillary flow restrictor (5) and the annulus flow restrictor (see FIG. 7(b)).

The source tube, growth tube and cross member, in which transport takes place, are fabricated from quartz and the system is demountable with ground glass joints between the cross member and the two vertical tubes allowing removal of grown crystals and replenishment of source material. Radiation shields (not shown) together with the vacuum jacket which surrounds the entire system provide thermal insulation. A flow restrictor (either a capillary or a sintered quartz disc) is located in the centre of the cross member. Growth takes place on a substrate located in a quartz block in the growth tube with the gap between this glass block and the quartz envelope forming the downstream flow restrictor. Provision is made for a gas inlet to the source tube and the growth tube may be pumped by a separate pumping system or by connection to the vacuum jacket via a cool dump tube. This system provides the following: firstly, source and growth regions are thermally decoupled making the achievement of optimum axial and radial temperature profiles in the growth region more tractable, secondly, it is possible to observe both the growing surface and source material directly during growth allowing, for example, optical pyrometry or spectrometric measurements as a diagnostic for the growth process, thirdly, the layout provides for in situ measurement of the vapour pressures of the source elements by means of optical absorption measurements made through the cross-member on either side of the flow restrictor. If the flow properties of the flow restrictor are known, then these measurements also allow the mass transport rate to be determined directly during growth and fourthly, the glassware is relatively simple and robust and may, in principle, be extended to the growth of multinary compounds by the addition of source tubes connected to the growth tube by suitable flow restrictors (designed to minimise reverse flow of species and hence contamination of the source material by operating at a sufficiently high flow rate).

FIG. 7(a) shows a flow restrictor of the prior art and FIG. 7(b) shows a flow restrictor of the present invention. The seed pedestal (4) upon which the seed crystal (3) is mounted also provides the annulus flow restriction. This is achieved by a combination of the annulus gap and length of the pedestal. By modifying the shape of the pedestal, the size of the crystal to be grown and the flow restrictor function can be decoupled. This also assists with the requirement for crystal growth away from the walls of the growth chamber. A further aspect of this invention is that in addition to the number of crystals being grown at the same time, the crystals may have varying diameter depending on the shape of the pedestal. It is also possible to add dopant impurities at different levels into each individual growth chamber.

1. Apparatus for vapour phase crystal growth to produce multiple single crystals in one growth cycle comprising:
at least one central source chamber;
a plurality of growth chambers;
a plurality of passage means adapted for transport of vapour from the source chamber to the growth chambers wherein the at least one source chamber is thermally decoupled from the growth chambers.

2. An apparatus as claimed in claim 1 which simultaneously produces at least two different crystals of different properties.

3. An apparatus as claimed in claim 1 or 2 wherein the input into the growth chamber is varied.

4. An apparatus as claimed in claim 3 wherein a dopant is added into the growth chamber.

5. An apparatus as claimed in claim 1 wherein the flow rate into the growth chamber is varied.

6. An apparatus as claimed in claim 1 wherein each growth chamber comprises a growth tube containing a seed crystal.

7. An apparatus as claimed in claim 6 wherein the seed crystal is supported on a pedestal or surface.

8. An apparatus as claimed in claim 7 wherein the length of the pedestal in each growth chamber is different.

9. An apparatus as claimed in claim 7 wherein the pedestal height range is from approximately 2 to 40 mm.

10. An apparatus as claimed in claim 1 which additionally comprises means for in-situ monitoring of the growth chamber which is non-intrusive in terms of temperature regulation within the growth chamber.

11. An apparatus as claimed in claim 1 wherein the passage for transport of vapour deviates by an angle of at least 5° along the length thereof between source and growth chambers thereby thermally isolating the source and growth chambers.

12. An apparatus as claimed in claim 1 wherein thermal decoupling is effected by means of flow restrictors, located remote from and between the source chamber and growth chambers.

13. An apparatus as claimed in claim 1 comprising just one central source chamber.

14. A process for bulk vapour phase crystal growth to produce multiple single crystals in one growth cycle comprising:
providing one reservoir of source material and a plurality of growth chambers each associated with independent temperature means; and transporting vapour phase material between the source and growth chambers.

15. The process as claimed in claim 14 in which the simultaneous formation of at least two different crystals of different properties occurs.

16. The process as claimed in claim 14 wherein the input into the growth chamber is varied.

17. The process as claimed in claim 14 wherein a dopant is added into the growth chamber.

18. The process as claimed in claim 14 wherein the flow rate into the growth chamber is varied.

19. An apparatus as claimed in claim 1 adapted for bulk vapour transport techniques.

20. An apparatus as claimed in claim 1 adapted for growth of crystals selected from compounds of groups IIA, IIB, III, V, VI and VII and from compounds of Group IV of the Periodic Table of Elements.

21. An apparatus as claimed in claim 4 wherein the dopant is chlorine, indium, copper or zinc.

22. An apparatus as claimed in claim 9 wherein the pedestal height is approximately 10 mm.

23. The process as claimed in claim 17 wherein the dopant is chlorine, indium, copper or zinc.

24. The process as claimed in claim 14 wherein the crystals are semiconductor, optoelectronic or optical crystals.

25. The process as claimed in claim 14 wherein the crystals are grown from elemental, polycrystalline binary, ternary or other multinary compounds.

26. The process as claimed in claim 14 wherein the crystals are grown from compounds of groups IIA, IIB, III, V, VI and VII and from compounds of Group IV of the Periodic Table of Elements.

27. The process as claimed in claim 26 wherein the crystals are grown from compounds of groups II and VI and from compounds of Group IV of the Periodic Table of Elements.

28. The process as claimed in claim 26 wherein the crystals are grown from compounds of Be, Mg, Zn, Cd, Hg, S, Se, Te or I.

29. The process as claimed in claim 26 wherein the crystals are grown from compounds of Si or C.
